(19) United States
(12) Patent Application Publication
(10) Pub. No.: US 2019/0248813 A1
(43) Pub. Date: Aug. 15, 2019

(54) PHOTOVOLTAICALLY ACTIVE PEROVSKITE MATERIALS

(71) Applicant: University of Kent, Canterbury (GB)

(72) Inventor: Mark Andrew Green, Canterbury (GB)

(73) Assignee: University of Kent, Canterbury (GB)

(21) Appl. No.: 16/342,019

(22) PCT Filed: Oct. 13, 2017
(86) PCT No.: PCT/GB2017/053091

§ 371 Date: Apr. 15, 2019

(30) Foreign Application Priority Data
Oct. 13, 2016 (GB) 1617385.8

(51) Int. Cl. C07F 7/24; H01L 51/00

(52) U.S. Cl. CPC C07F 7/24; H01L 51/5012; H01L 51/0077

(57) ABSTRACT

The invention provides a material with perovskite-type structure having a formula selected from Formula I and Formula II. in which A′ represents one or more monovalent cations that can be selected from alkali metal ions, (organo)ammonium and (organo)phosphonium ions; A″ represents one or more divalent cations that can be selected from alkaline earth metal cations; A′″ represents one or more trivalent cations that can be selected from lanthanide ions; a, b and c are each in the range of from 0 to 1, a+b+c=1; x=a+2b+3c; d is in the range of from 1 to 5, each of e, f and g are in the range of from 0 to 1. with the proviso that g is less than 1 in Formula I; e+f+g−1; y=2(e+f)+3g; each X in “X” and “X2” is independently selected from the halogens; and h is in the range of from 0.0001 to 0.2. X2 is a dihalogen moiety, and can be the source of a valence band “hole” in the photovoltaic semiconducting material. The invention also relates to photovoltaic devices or a surface coating that comprises the material.

### TECHNICAL FIELD

The invention relates generally to photovoltaically active halide-containing perovskite-type materials that can be used in photovoltaic devices such as solar cells. The invention also relates to devices comprising the perovskite-type materials.

### BACKGROUND

Photovoltaic systems comprising solar cells are widely employed to generate electricity, and are particularly advantageous for off-grid, remote electrical power generation. However, they are also widely used in urban environments, not only to reduce consumption from the grid (and hence to mitigate power costs), but also as a possible source of income by feeding any generated electrical power back into the grid. Large-scale installations of solar panels for renewable and sustainable energy generation, often termed solar farms or solar parks, are becoming increasingly common.

However, the commercial appeal of photovoltaic systems is highly dependent on several factors, for example oil and gas prices, and also local tax and subsidy arrangements. Even with favourable tax and subsidy regimes, recovery of installation and capital costs can often take several years. However, even with these apparent drawbacks, deployment of photovoltaic energy generation is increasing.

The commercial appeal of photovoltaic systems would benefit even further from reduced fabrication costs and improved photovoltaic yield. This would further assist in reducing reliance on combustion of mineral fuels for electricity generation, so helping to mitigate carbon dioxide emissions.

Organometal halide perovskite materials, such as methylammonium lead iodide, have received increasing attention as photovoltaic materials in view of their relatively facile synthesis via wet chemistry methods, and reportedly high photovoltaic efficiencies. However, there is still a need for materials that are facile to synthesise, and which have photovoltaic efficiencies.

### SUMMARY OF INVENTION

The present invention provides a material with perovskite-type structure having a formula selected from Formula I and Formula II below:

$$\begin{matrix}{[ {A}_{a}^{′} {A}_{b}^{″} {A}_{c}^{′′′} ]}_{( \frac{3 - y}{x} )} [ {Sn}_{e} {Pb}_{f} {Bi}_{g} ] {\{ {{[ X ]}_{( 1 - 2 h )} [ {X}_{2} ]}_{h} \}}_{3} & Formula I \\ {{[ {A}_{a}^{′} {A}_{b}^{″} {A}_{c}^{′′′} ]}_{( \frac{d + 3 - y}{x} )} [ {Sn}_{e} {Pb}_{f} {Bi}_{g} ]}_{d} {\{ {{[ X ]}_{( 1 - 2 h )} [ {X}_{2} ]}_{h} \}}_{3 d + 1} & Formula II\end{matrix}$$

A′ represents one or more monovalent cations. These can be selected from alkali metal ions, quaternary (organo)ammonium ions of formula [H_{4-z}R_{z}N] and quaternary (organo)phosphonium ions of formula [H_{4-z}R_{z}P], in which each R is independently selected from C₁₋₄ alkyl, optionally comprising a substituent group selected from one or more of halide, hydroxyl, amino, C₁₋₂ alkoxy, C₁₋₂ alkylamino and C₁₋₂ haloalkyl, and z is in the range of from 0 to 4;

A″ represents one or more divalent cations, which can be selected from alkaline earth metal cations.

A′″ represents one or more trivalent cations, which can be selected from one or more lanthanide elements.

Each of a, b and c is in the range of from 0 to 1, a+b+c=1, and x=a+2b+3c.

d is in the range of from 1 to 5.

Each of e, f and g is in the range of from 0 to 1, e+f+g=1, and y=2(e+f)+3g. In Formula I, g is less than 1.

Each X in “X” and “X₂” is independently selected from one or more of the halogens, typically from Cl, Br and I.

h is in the range of from 0.0001 to 0.20.

The invention also provides a photovoltaic device, such as a solar cell, comprising the above perovskite-type material.

The invention additionally provides a method for producing electricity, comprising exposing a photovoltaic device as mentioned above to electromagnetic radiation in the UV and/or visible region.

The invention further provides the use of dihalogen molecules within a perovskite-type material as described above to create a valence band hole in the perovskite-type material.

### BRIEF DESCRIPTION OF THE DRAWINGS

The present invention will now be described with reference to the accompanying drawings, in which:

FIG. 1 illustrates the structure of methylammonium lead iodide, showing lead and iodide positions in the room temperature I4/m space group, showing four crystallographically inequivalent iodide positions within the unit cell at position I1 and I2 that form regular perovskite PbI₆ corner shared octahedral, and two additional positions I2A and I3 (methylammonium ions are omitted for clarity);

FIG. 2 shows the results of MEM analysis of the I2 position, showing density at the I2 position, and additional densities at two other positions, I2A, in close proximity;

FIG. 3 shows changes in the dimensions of the unit cell of methylammonium lead iodide with temperature, as measured using synchrotron x-ray diffraction;

FIG. 4 shows changes in the occupancies of the I1, I2 and I2A sites with temperature, based on the synchrotron x-ray data;

FIG. 5 illustrates the mechanism for molecular iodine formation in methylammonium lead iodide;

FIG. 6 shows the representative local structure of methylammonium lead iodide after diatomic iodine formation, highlighting the relative positions of I₂ molecules compared to the perovskite framework(methylammonium ions are omitted for clarity);

FIG. 7 illustrates cooperative arrangements of the orientation of the methylammonium ions as a result of occupation of I3 sites;

FIG. 8 shows the x-ray scattering density map of the CH₃NH₃ molecule;

FIG. 9 shows the nuclear scattering density map of CH₃NH₃ (isosurface level of 1.0 fmÅ⁻³), showing C and N (inner tetrahedron) and hydrogen scattering (outer scattering); and

FIG. 10 illustrates a molecular representation of CH₃NH₃ based on the maxima in the scattering density maps.

### DESCRIPTION OF EMBODIMENTS

The present invention relates to photovoltaically active materials whose structures are based on the perovskite structure, and which contain dihalogen moieties within the structure. The dihalogen moieties form part of a semiconductor electron-hole pair, acting as the source of the “hole” which imparts or induces semiconducting and photovoltaic properties.

### Composition

The photovoltaically active perovskite-type materials have a formula according to Formula I or Formula II above.

In embodiments, A′ comprises or consists of one or more organoammonium or organophosphonium ion, in which R is selected from C₁₋₄ alkyl, for example C₁₋₂ alkyl. In other embodiments, R is selected from C₁₋₄ alkylamino, for example C₁₋₂ alkylamino, e.g. from methylamino (H₂N—CH₂—) and ethylamino (H₂N—CH₂CH₂—). z is typically less than 4, and in embodiments is 1. In some embodiments, A′ represents organoammonium ions. In certain embodiments, R is [CH₃H₃N]⁺.

In the organoammonium or organophosphonium ions, the alkyl or substituted alkyl groups can be linear or branched. In the case of C₃₋₄ alkyl or substituted alkyl, the alkyl can also be cyclic.

Where A′ comprises alkali metal ions, these are typically selected from Rb and Cs.

In embodiments, A″ represents one or more divalent cations, selected from alkaline earth metal cations. Where A″ comprises alkaline earth metals, they are typically selected from Sr and Ba.

In embodiments, A′″ represents one or more trivalent cations, selected from one or more lanthanide elements.

The value of x is dependent on the respective ratios of A′, A″ and A′″, i.e. on the values of a, b and c. When a=1, x=1. When b=1, x=2. When c=1, x=3. When there is a mixture of two or more of A′, A″ and A′″, i.e. at least two of a, b and c are greater than 0, x is an intermediate value based on the ratio of monovalent, divalent and trivalent cations. The value of x is determined by the equation: x=a+2b+3c. Thus, as an example, if the material comprises on a molar basis 60% of A′, 30% of A″ and 10% of A′″ (i.e. a=0.6, b=0.3 and c=0.1), then x=0.6+(2×0.3)+(3×0.1)=1.3.

In embodiments, c is in the range of from 0 to 0.2, for example 0 to 0.1. In further embodiments, c=0.

The “X” in “X” and “X₂” can be the same of different. Typically X in both “X” and “X₂” represents the same halogen, although mixtures are also possible. In embodiments, X is selected from Br and I, and in further embodiments all occurrences of X are either Br or I. In still further embodiments, all occurrences of X are I.

Where X represents more than one halogen, one halogen will typically predominate. In one embodiment, the predominant halogen constitutes at least 90% or 95% on a molar basis of all halogens present. In embodiments, iodine is the predominant halogen.

X₂ denotes a molecular dihalogen entity within the perovskite-type structure. It can be formed from a redox couple according to the general equation:

2X⁻→X₂+2e⁻

The X₂ represents a molecular moiety, with a bond length that is comparable to that of a neutral X₂ molecule not confined within a perovskite or perovskite-type structure. By comparable is meant that the distance in A units of the X₂ molecule in the perovskite or perovskite-type structure is the same as the corresponding distance in an unconfined neutral X₂ molecule to 2 significant figures ±0.1 Å. For example, in the case of solid elemental iodine, the I—I bond distance is 2.68 Å, i.e. 2.7 Å to 2 significant figures. Corresponding I—I bond distances in the perovskite-type structures of the present invention are typically 2.7±0.1 Å, i.e. in the range of from 2.6 to 2.8 Å.

Where there are mixtures of halogen, X₂ can comprise the same or different halogen atoms, e.g. X₂ can be selected from I₂, Br₂, C₂, IBr, ICl and BrCl. For example, if all X are selected from iodine and bromine, the perovskite-type material can comprise I₂, Br₂ and IBr species. The relative amounts of mixed and non-mixed dihalogen molecules depend inter alia on the relative overall amounts of each of the halides present in the material.

h is in the range of from 0.0001 to 0.20, and is typically in the range of from 0.0002 to 0.10, such as from 0.0005 to 0.07. The value of h is tailored to achieve a balance of improving photovoltaic efficiency (which can be achieved by increasing h), while avoiding too much structural disruption (which can result from h being too high).

The materials comprise one or more of Sn, Pb and Bi, in the molar ratios SnₑPb_{f}Bi_{g}, where each of e, f and g is in the range of from 0 to 1, and e+f+g=1. In Formula I, g is less than 1, and is typically 0.5 or less.

In embodiments, g is 0.2 or less. In other embodiments, g=0. In further embodiments, the amount of tin is no more than 20% of that of lead on a molar basis, i.e. f≥4e. In still further embodiments, f=1.

The value of y is dependent on the ratios of Sn, Pb and Bi, i.e. the values of e, f and g. When e+f=1 (i.e. when the material comprises tin and/or lead, but not bismuth), then y=2. When g=1 (i.e. when the material comprises bismuth, but no tin and lead), y=3. When (e+f) and g are each greater than 0 and less than 1, (i.e. when there is a mixture of bismuth with tin and/or lead), then y is an intermediate value based on the molar ratios, calculated from 2(e+f)+3g. Thus, as an example, if the material comprises Sn_{0.1}Pb_{0.7}Bi_{0.2} (i.e. e=0.1, f=0.7 and g=0.2), then y=(0.8×2)+(0.2×3)=2.2.

d is an integer in the range of from 1 to 5, for example from 2 to 5. Typically, d is from 1 to 4 or 2 to 4. In embodiments, d is 1 or 2.

The value of x can be dependent on the value of y. Thus, in embodiments, y can be less than or equal to 2.5, and x can be less than or equal to 1.5. In further embodiments, y can be less than or equal to 2.2, and x can be less than or equal to 1.1. In still further embodiments, y=2 and x=1.

In embodiments, the materials have a composition according to Formula I.

$${{{[ {A}_{a}^{′} {A}_{b}^{″} {A}_{c}^{′′′} ]}_{( \frac{3 - y}{x} )} [ {Sn}_{e} {Pb}_{f} {Bi}_{g} ] [ X ]}_{3 - 2 h} [ {X}_{2} ]}_{h} \qquad Formula I$$

In these embodiments, the material can adopt a conventional “perovskite” structure. Typically, c=0.1 or less or c=0. Typically, b is 0.2 or less. Typically, a is 0.8 or more. g is less than 1, more typically g is 0.5 or less, for example 0.2 or less or 0.1 or less, or g=0. Typically, y is 2.2 or less, for example y can be 2.

In other embodiments, the materials have a composition according to Formula II.

$${{[ {A}_{a}^{′} {A}_{b}^{″} {A}_{c}^{′′′} ]}_{( \frac{d + 3 - y}{x} )} [ {Sn}_{e} {Pb}_{f} {Bi}_{g} ]}_{d} {\{ {{[ X ]}_{( 1 - 2 h )} [ {X}_{2} ]}_{h} \}}_{3 d + 1} \qquad Formula II$$

In these embodiments, particularly where d=2 or more, the material can adopt a perovskite-type structure in which perovskite layers are separated with intrusion layers of a different phase (e.g. adopting a Ruddlesden-Popper structure) as described further below.

In these embodiments, d is typically in the range of from 1 to 5 of from 2 to 5, for example from 1 to 3 or from 2 to 3, and y=2.2 or less, for example y=2. Typically, c is 0.1 or less, for example c=0. Typically, b is 0.2 or less. Typically, a is 0.8 or more.

### Photovoltaic Properties

The perovskite-type materials of the present invention are photovoltaically active, in that they can produce electric current at ambient temperatures when exposed to light in the UV/visible region of the electromagnetic spectrum, e.g. with wavelengths in the range of from 400-700 nm. The band gap (between the valence and conduction bands) associated with materials of the present invention is typically in the range of from 1.5 to 2.5 eV.

### Structure

The perovskite type materials of the present invention comprise perovskite layers that are optionally interspersed with different layers or intrusions.

Conventional perovskite materials adopt the structure of CaTiO₃, whereas structures comprising perovskite layers with intrusions include the Ruddlesden-Popper structure, as exhibited for example by Sr₂TiO₄

Formula I describes materials having a three dimensional perovskite structure:

$${[ {A}_{a}^{′} {A}_{b}^{″} {A}_{c}^{′′′} ]}_{( \frac{3 - y}{x} )} [ {Sn}_{e} {Pb}_{f} {Bi}_{g} ] {\{ {{[ X ]}_{( 1 - 2 h )} [ {X}_{2} ]}_{h} \}}_{3} \qquad Formula I$$

In embodiments, the materials adopt the perovskite structure defined by Formula I.

Formula II describes materials having layered Ruddlesden Popper Structures

$${{[ {A}_{a}^{′} {A}_{b}^{″} {A}_{c}^{′′′} ]}_{( \frac{d + 3 - y}{x} )} [ {Sn}_{e} {Pb}_{f} {Bi}_{g} ]}_{d} {\{ {{[ X ]}_{( 1 - 2 h )} [ {X}_{2} ]}_{h} \}}_{3 d + 1} \qquad Formula II$$

In embodiments, the materials adopt the layered Ruddlesden Popper structure defined by Formula II.

The Ruddlesden Popper phases, which are closely related to the three-dimensional perovskite structure, as discussed by Ruddlesden et al, Acta Cryst, 11, 54 (1958), contain two dimensional slabs of perovskite, which are separated with AX layers. The properties of such Ruddlesden Popper materials are often found to be very similar to those of Perovskite materials. Some examples of these similar properties are provided below:
Microwave dielectrics [Lee et al, Nature 502, 532 (2013)];
Colossal Magnetoresistance in Manganese Oxides [Battle et al, Chem. Mater 9, 552 (1997)];
Semiconducting photovoltaics [Stoumpos et al, Chem Mater 28, 2852 (2016), Tsai et al, Nature 536, 312 (2016)]; and
Ferroelectrics [Stone et al, Nature Comm. 7, 12572 (2016)].

An introduction to these phases can be found at Structure of Materials: An introduction to Crystallography, Diffraction and Symmetry, De Graef and McHenry (Cambridge University Press, 2012)

In the present invention, the perovskite-type structures of Formulae I and II typically comprise Pb and/or Sn as the predominant element compared to Bi, i.e. e+f>0.5. In further embodiments, e+f can be greater than or equal to 0.8.

d represents the relative molar quantity of the tin, lead and/or bismuth in the material. In embodiments, the materials have the perovskite structure, and d=1. In other embodiments, the material adopts other perovskite-type structures (such as Ruddlesden-Popper) and have d values in the range of from 1 to 5, for example from 2 to 5, from 2 to 4 or from 2 to 3.

The materials of the present invention can be crystalline, and can have a tetragonal unit cell, i.e. the unit call can have a tetragonal space group. In other embodiments, the space group can be orthorhombic. In further embodiments, the space group can be cubic. The same perovskite or perovskite type material can undergo transitions between space groups, for example on heating or cooling. The space group and unit cell parameters will depend inter alia on the size of cations A′, A″, A′″ and halogen X, and their mobility within the structure. In one embodiment, the perovskite-type material has a tetragonal or rhombohedral space group, and can change to cubic on heating.

When transitioning from tetragonal or orthorhombic to cubic, the unit cell dimensions converge until it becomes cubic. This change in unit cell dimensions can be subject to hysteresis. For example, on heating, the cubic space group can be formed at a temperature Tₕ, whereas the temperature which the cubic space group begins to transition back to a tetragonal or orthorhombic space group when cooled is at a different temperature, T_{c}. Typically, Tₕ is greater than T_{c}.

It has been found that this transition between space groups and unit cell dimensions is accompanied by the formation of dihalogen moieties within the structure, i.e. the more “cubic” the space group, the more dihalogen there is.

The compounds of the present invention can be produced, and/or the dihalogen content can be controlled, by heating the material from a starting temperature, Tₛ, to a temperature at or above Tₕ, i.e. the temperature where the unit cell becomes cubic on heating, and then cooling the material to a temperature below T_{c}, and at or above Tₛ. Cooling below Tₛ is also possible, so long as the cell parameters (a, b, c) are less divergent compared to the values at Ts.

In embodiments, the starting temperature Tₛ can be in the range of from 0 to 35° C., for example 0 to 25° C., or at ambient temperature.

In embodiments, Tₕ is 40° C. or more, for example 50° C. or more, or 55° C. or more.

In embodiments, T_{c} is 50° C. or less, for example 45° C. or less, or 35° C. or less.

The changes in space group and unit cell parameters will be dependent on the individual material, but can be determined by routine means, for example by x-ray powder diffraction or single crystal x-ray diffraction.

The present invention relates to the surprising discovery that the presence of the I₂ molecule within the hybrid perovskites imparts or induces semiconducting and photovoltaic properties. A process of producing materials according to Formula I and II, or of controlling the content of dihalogen, by heating is provided hereinabove.

In the paper Iodide management in formamidinium-lead-halide-based perovskite layers for efficient solar cells [Yang et al., Science 356, 1376 (2017)], which was published on 23 Jun. 2017, after the priority date of the present application, Yang et al describe an alternative process for producing such materials by the artificial addition of a source of I₂ to the solar films. Yang et al report a substantial increase in the power conversion efficiency to the highest certified value in the perovskite cells of 22.1%, thus providing supporting evidence of the effect of I₂ within the structure as described in the present application and in the subsequent publication Minns et al [Nature Comm. 8, 15152 (2017)].

### Devices

The perovskite-type materials of the invention are photovoltaically active, and can be incorporated into a photovoltaic device, for example a solar cell, a photodiode, a light emitting diode or a photodetector.

In the materials of the invention, the formation of formally neutrally charged X₂ moieties effectively creates an electron-hole pair, and acts as a molecular equivalent to nanostructured junctions formed in conventional semiconductor photovoltaics. The perovskite-type materials can conduct both electrons and holes, and therefore separate junctions with other n-type or p-type semiconductors are not required in order to exhibit photovoltaic activity. This may contribute to their large electron/hole diffusion length, which can be of the order of micrometers, and means that thin film fabrication is possible (e.g. using vapour deposition, spin coating or thin film crystallisation techniques), which reduces the complexity of photovoltaic devices, and also enables smaller units to be made.

In addition, because the present materials do not need multi-layered junctions in fixed panels, they can be applied on any surface exposed to light. For example, the perovskite-type materials could be incorporated into or applied as a surface coating or paint to structures that are exposed to light, for example to the walls, windows or roofs of buildings, to roads and pavements, to the outside of vehicles, or to the outside of portable electronic devices such as mobile phone or tablet screens and casings. Therefore, perovskite-type materials of the invention can be incorporated into a composition, for example a surface coating or paint, that can be applied to a surface. Photovoltaic properties can then be exploited by incorporating suitable electrodes.

### EXAMPLES

The structure of the perovskite type materials under various conditions has been studied on an example compound, namely methylammonium lead iodide, referred to below as “MAPbr”, with a notional formula [CH₃H₃N]PbI₃, and which adopts a perovskite structure.

Single crystals of the compound were prepared by slow evaporation of CH₃NH₃I and PbI₂ in γ-butyrolactone over 14 days. Some crystals were ground to perform powder neutron diffraction and powder x-ray diffraction studies. Single crystal X-ray diffraction studies were carried out on cleaved crystals.

Powder neutron diffraction data were collected on the BT1 diffractometer at NCHR, National Institute of Standards and Technology, Gaithersburg, Md., USA, using a Ge(311) monochromator (λ=2.0787(2) Å). Single crystal X-ray diffraction data were collected on a dual-source Rigaku Oxford Diffraction Supernova diffractometer. Power synchrotron diffraction was performed at the Swiss-Norwegian beamline (SNBL) at the ESRF (European Synchrotron Radiation Facility), Grenoble, France. Whole pattern fitting based on MEM (maximum entropy method) was carried out using the programs PRIMA and RIETAN, with a 256×256×256-pixel density map. MEM density maps were analysed using the Vesta program.

MEM analysis can be applied to diffraction data to generate density maps without prior knowledge of symmetry and unit cell contents, and is therefore unbiased towards any specific structural model. It can provide information on subtle local distortions even when the scattering is extremely weak compared to bulk diffraction.

MAPbI undergoes a number of structural phase transitions as a function of temperature, including an orthorhombic-tetragonal-cubic transition that is found in other perovskites as a result of mismatch of cation and anion size, which is further influenced by the non-symmetric methylammonium ion.

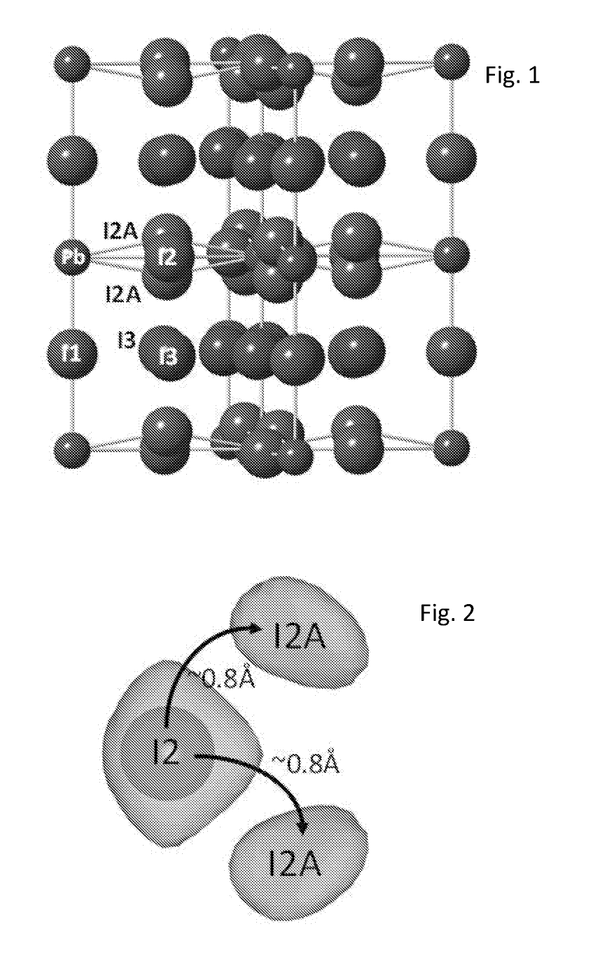

Powder neutron and single crystal x-ray diffraction analysis of the compound revealed a tetragonal perovskite structure with 14/m space group, and lattice parameters of a=8.8756(1) Å and c=12.6517(3) Å. The room temperature structure is shown in FIG. 1.

FIG. 1 highlights 4 crystallographically distinct iodine sites, namely I1, I2, I2A and I3. Methylammonium ions are not shown for clarity. FIG. 2 shows the results of MEM analysis of the (−0.2148-0.2851 0.5) I2 position, in which the nuclear scattering density at room temperature shows not only density at the I2 position, but also additional densities at two other positions, I2A, in close proximity. These were determined to be at (−0.252−0.248 0.453), approximately 0.8 Å from the I2 position demonstrating static disorder of the I2 site.

The I2A positions are offset towards the methylammonium ions situated in the cavity between I2 positions, and lie on either side of a mirror plane in the tetragonal space group.

A further iodide position, I3, was observed in the powder neutron diffraction data, powder synchrotron x-ray diffraction data, and single crystal x-ray diffraction data, which sits in an interstitial site in the z=0.25 plane, together with the Pb and methylammonium ions, as shown in FIG. 1.

Iodide position I1 sits in the apical position in the PbX₆ octahedra.

The dimensions of the unit cell change with temperature, as measured using synchrotron x-ray diffraction, are shown in FIG. 3. On heating from room temperature (i.e. Tₛ) to 335K (corresponding to Tₕ), the two lattice parameters of the tetragonal unit cell converge until they are equal, resulting in a cubic unit cell. On further heating, the lattice parameters increase, although the cubic symmetry is maintained.

On cooling, the cubic symmetry is maintained until a temperature of 320K (corresponding to T_{c}), below which the unit cell begins to revert back to tetragonal symmetry.

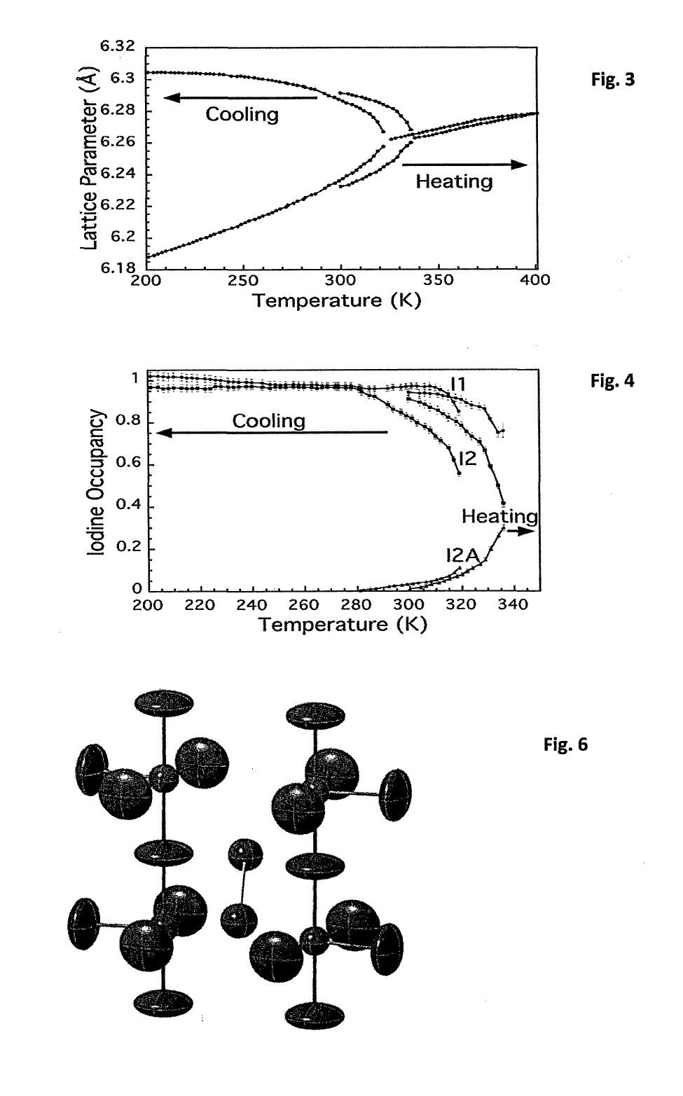

These changes correlate with changes in the occupancies of the I1, I2 and I2A sites, also based on the synchrotron x-ray data, as shown in FIG. 4. On heating, occupancy of I2 sites dropped significantly at temperatures above 280K, which also corresponded with an increase in site I2A occupancy. I1 occupancy decreases to a lesser extent close to the transition to cubic unit cell. The occupancy of 13 was difficult to determine accurately, implying that it was disordered and diffuse and contributed weakly to Bragg scattering. Because the total occupancy of I1+I2+I2A+I3 appeared to drop on heating, this is evidence that I3 occupancy was increasing.

The mechanism of what is happening is illustrated in FIG. 5. Initially (FIG. 5a) iodide ions can be found in positions I1 and I2. An iodide in position I2 migrates to I3 (FIG. 5b). The distances between the I3 position, the two still occupied I1 positions and the remaining I2 position are all roughly equal, with I3-I11 distances at 3.21 and 3.22 Å, and an I3−I2 distance of 3.24 Å (FIG. 5c).

The remaining I2 position shifts approximately 0.8 Å to position I2A (FIGS. 5c and 5d). From the diffraction data, two I3−I2A distances of 2.7(1) Å and 2.6(1) Å are identified.

For comparison, I—I bond distances in the [I₃]⁻ ion in orthorhombic CsI are 2.84 Å and 3.04 Å. I—I distances in solid I₂ are 2.68 Å for the primary covalently bound atoms, with intermolecular distances of 3.56 Å. For I₂ confined in zinc formate (Zn₃[HCOO]₆), the I—I bond length is 2.691 Å, with an intermolecular distance of 3.59 Å. For the [I_{2]}⁺ ion, in ISb₂F₁₁, the I—I distance is 2.56 Å.

This demonstrates that neutral, diatomic I₂ molecules are formed in the perovskite structure, the extent of which is controllable by heating and cooling the structure.

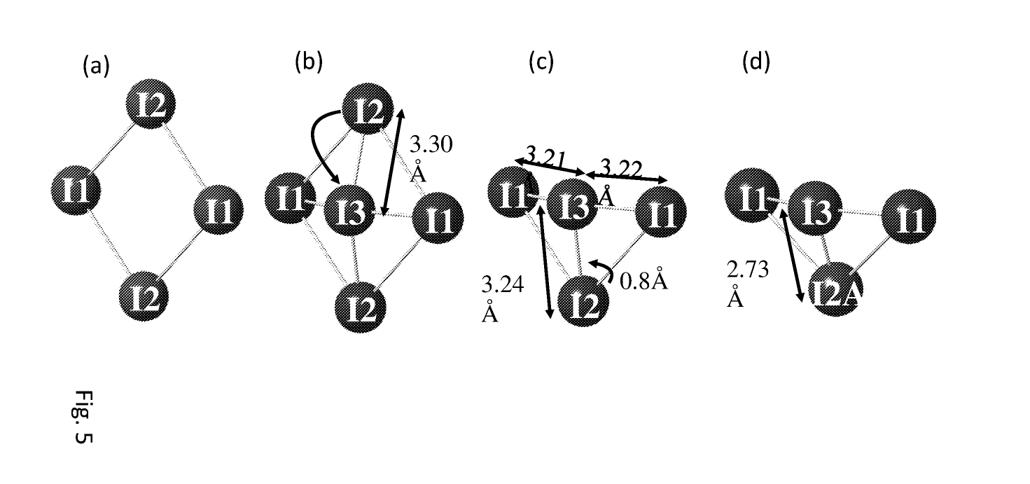

The resulting structure is illustrated in FIG. 6, highlighting the diatomic I2 molecule between two lead centres, based on migration of ions at two I₂ locations to an 13 and an I2A location, and results in a potential chain of I2 and I⁻ ions along the z axis of the structure.

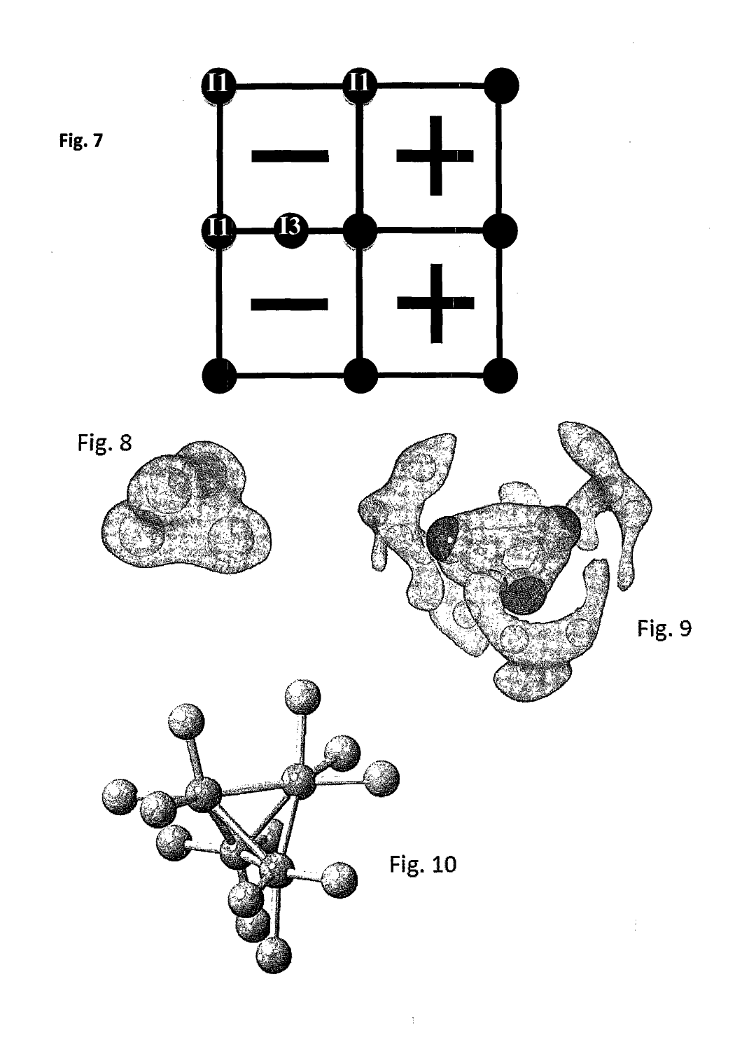

With regard to the methylammonium ions, FIG. 7 illustrates that the orientation is dependent on the occupancy of the I3 position. In FIG. 7, “+” represents two possible orientations of the molecule methyl ammonium moiety where there is no adjacent iodine in the I3, whereas “−” represents that only one orientation is possible when an adjacent I3 site is occupied.

MEM density maps surrounding the methylammonium ion from x-ray powder diffraction showed similar scattering for C and N, and revealed a 4 atom unit in a tetrahedral configuration as shown in FIG. 8. The centre of the tetrahedron lies at the centre of the site between I2 positions. MEM density maps from the powder neutron diffraction data reveal the same C—N “tetrahedron”, and also density from six hydrogen atom positions just over 1 Å from the C or N positions, as shown in FIG. 9. FIG. 10 shows a molecular representation based on the maxima in the density maps.

The results demonstrate that there is considerable rotational and librational disorder in the methylammonium ion and identifies two orientations, one in the (220) plane, and another in the (22̅0) plane. The orientations point exactly between the iodide positions, I2, in the z=0.25 plane. However, whereas the centre of mass of the two orientations also lie at z=0.25, the two individual orientations were found to be at off-centre positions of z=0.234 and 0.266.

### Summary

Dihalogen moieties can be formed in perovskite-type materials of Formula I, the amount of which can be controllable, for example by heating and cooling the material. The extent of dihalogen formation can be correlated with changes in unit cell symmetry, for example tetragonal to cubic, and can act as the source of an electron-hole pair that gives rise to photovoltaic activity.

What is claimed is:

1. A material with perovskite-type structure of Formula I below:
$$\begin{matrix}{[ {A}_{a}^{′} {A}_{b}^{″} {A}_{c}^{′′′} ]}_{( \frac{3 - y}{x} )} [ {Sn}_{e} {Pb}_{f} {Bi}_{g} ] {\{ {{[ X ]}_{( 1 - 2 h )} [ {X}_{2} ]}_{h} \}}_{3} & Formula I \\ {{[ {A}_{a}^{′} {A}_{b}^{″} {A}_{c}^{′′′} ]}_{( \frac{d + 3 - y}{x} )} [ {Sn}_{e} {Pb}_{f} {Bi}_{g} ]}_{d} {\{ {{[ X ]}_{( 1 - 2 h )} [ {X}_{2} ]}_{h} \}}_{3 d + 1} & Formula II\end{matrix}$$
wherein:
A′ represents one or more monovalent cations;
A″ represents one or more divalent cations;
A′″ represents one or more trivalent cations;
Each of a, b and c is in the range of from 0 to 1, and a+b+c=1;
x=a+2b+3c;
d is in the range of from 1 to 5;
Each of e, f and g is in the range of from 0 to 1, and e+f+g=1, with the proviso that g is less than 1 in Formula I;
y=2(e+f)+3g;
each X in “X” and “X₂” is independently selected from the halogens; and
h is in the range of from 0.0001 to 0.20.

2. A material as claimed in claim 1, in which;
A′ is selected from alkali metal ions, quaternary (organo) ammonium ions of formula [H_{4-z}R_{z}N] and quaternary (organo) phosphonium ions of formula [H_{4-z}R_{z}P], in which each R is independently selected from C₁₋₄ alkyl, optionally comprising a substituent group selected from one or more of halide, hydroxyl, amino, C₁₋₂ alkoxy, C₁₋₂ alkylamino and C₁₋₂ haloalkyl, and z is in the range of from 0 to 4; and/or
A″ is selected from one or more divalent cations selected from alkaline earth metal cations;
and/or A′″ is selected from one or more of the lanthanides.

3. A material as claimed in claim 1, in which each X is independently selected from Cl, Br and I.

4. A material as claimed in claim 1, in which all occurrences of X are the same halogen, for example iodine.

5. A material as claimed in claim 1, in which g is in the range of from 0.0002 to 0.10.

6. A material as claimed in claim 1, in which e+f is 0.8 or more.

7. A material as claimed in claim 1, in which f=1.

8. A material as claimed in claim 1, in which A′ is selected from quaternary organoammonium ions [H_{4-z}R_{z}N], in which z is from 1 to 4.

9. A material as claimed in claim 1, in which each R is independently selected from C₁₋₄ alkyl and C₁₋₄ alkylamino.

10. A material as claimed in claim 1, in which z is less than 4, or z is 1.

11. A material as claimed in claim 1, in which the band gap between the valence and conduction bands is in the range of from 1.5 to 2.5 eV.

12. A material as claimed in claim 1, having a tetragonal or orthorhombic unit cell at a temperature of Tₛ or less, and having a cubic unit cell when heated to a temperature of Tₕ or more, in which Tₕ is greater than Tₛ.

13. A material as claimed in claim 12, in which Tₛ is 35° C. or less, and Tₕ is 40° C. or more.

14. A material as claimed in claim 1, in which the perovskite-type structure is a perovskite structure or a Ruddlesden-Popper structure.

15. A material as claimed in claim 1, in which the structure is of Formula I, adopts a perovskite structure, a=1, A′=[H_{4-z}R_{z}N] where z=1 and R is selected from =methyl and ethyl; e+f=1 and e is greater than 0.8; and g is in the range of from 0.0005 to 0.07.

16. A material as claimed in claim 1, in which the material is of Formula I, c is 0.1 or less, b is 0.2 or less, a is 0.8 or more, g is 0.2 or less, and y is 2.2 or less.

17. A material as claimed in claim 1, in which the material is of Formula II, d is in the range of from 2 to 5, e+f=1, y=2.2 or less, c is 0.1 or less, b is 0.2 or less, and a is 0.8 or more.

18. A photovoltaic device or surface coating comprising a material according to claim 1.

19. A photovoltaic device as claimed in claim 18, selected from a solar cell, a photodiode, a light emitting diode and a photodetector.

20. (canceled)

21. Use of dihalogen molecules within a material as claimed in claim 1, to create a valence band hole in the material.

22. Use of dihalogen molecules according to claim 21, in which the material is part of a photovoltaic device.

23. Use of dihalogen molecules according to claim 22, in which the photovoltaic device is a solar cell, a photodiode, a light emitting diode or a photodetector.
